(19) United States
(12) Patent Application Publication
(10) Pub. No.: US 2025/0096015 A1
(43) Pub. Date: Mar. 20, 2025

(54) RESIN SEALING DEVICE AND RESIN SEALING METHOD

(71) Applicant: APIC YAMADA CORPORATION, Nagano (JP)

(72) Inventors: Shusaku Tagami, Nagano (JP); Makoto Yanagisawa, Nagano (JP)

(73) Assignee: APIC YAMADA CORPORATION, Nagano (JP)

(21) Appl. No.: 18/728,897

(22) PCT Filed: Apr. 18, 2023
(86) PCT No.: PCT/JP2023/015468

§ 371 Date: Jul. 15, 2024

(30) Foreign Application Priority Data
Jun. 8, 2022 (JP) 2022-092898

(51) Int. Cl. H01L 21/67; H01L 21/56

(52) U.S. Cl. CPC H01L 21/67126; H01L 21/565

(57) ABSTRACT

A resin sealing device (1) includes: a resin sealing mold (21), configured to seal an electronic component (P) with resin by compression molding a resin material on a workpiece (W); and a resin amount calculation portion (79), configured to calculate a resin amount of the resin material to be supplied to the workpiece (W) for each workpiece based on a mounting state of the electronic component (P) in the workpiece (W). The resin material includes a first resin (R1) and a second resin (R2), the first resin (R1) is a sheet-like resin, and the second resin (R2) is a granulated resin, a powdered resin, or a liquid resin. A supply amount of at least the second resin (R2) among the first resin (R1) and the second resin (R2) is determined for each workpiece based on the resin amount calculated by the resin amount calculation portion (79).

### TECHNICAL FIELD

The present invention relates to a resin sealing device and a resin sealing method.

### RELATED ART

When electronic components such as semiconductor elements are sealed with resin, the supply amount of the resin may be adjusted based on the mounting states of the electronic components. For example, Patent Document 1 discloses a resin molding device that removes excess sheet-like resin corresponding to the mounting states of electronic components.

### CITATION LIST

### Patent Document

[Patent Document 1] Japanese Patent Application Laid-Open (JP-A) No. 2021-118244.

### SUMMARY

### Technical Problem

However, in the resin molding device disclosed in Patent Document 1, since excess sheet-like resin is removed from the workpiece, unnecessary sheet-like resin may be generated. In addition, the devices and processes may become complicated due to the need to transport and store the unnecessary sheet-like resin.

The present invention has been made in consideration of the above circumstances, and an object of the present invention is to provide a resin sealing device and a resin sealing method that may supply an appropriate amount of resin to each workpiece while eliminating waste of resin.

### Solution to Problem

A resin sealing device according to one aspect of the present invention is a compression molding type resin sealing device, configured to seal an electronic component of a workpiece including a substrate and the electronic component with resin, the resin sealing device including: a resin sealing mold, configured to seal the electronic component with rein by compression molding a resin material on the workpiece; and a resin amount calculation portion, configured to calculate, for each workpiece, a resin amount of the resin material to be supplied to the workpiece based on a mounting state of the electronic component in the workpiece. The resin material includes a first resin and a second resin, the first resin is a sheet-like resin, and the second resin is a granulated resin, a powdered resin, or a liquid resin. A supply amount of at least the second resin among the first resin and the second resin is determined for each workpiece based on the resin amount calculated by the resin amount calculation portion.

According to this aspect, the resin amount of the resin material to be supplied to the workpiece is calculated for each workpiece according to the mounting state of the workpiece, and the supply amount of the second resin is determined for each workpiece based on the calculated resin amount. Thus, for example, while supplying the first resin to the workpiece, the remaining resin amount may be adjusted to an appropriate amount by the second resin. As a result, an appropriate amount of resin may be supplied to each workpiece while eliminating waste of the resin supplied.

A resin sealing method according to another aspect of the present invention is a compression molding type resin sealing method for sealing an electronic component of a workpiece including a substrate and the electronic component with resin, the resin sealing method including: calculating, for each workpiece, a resin amount of a resin material to be supplied to the workpiece based on a mounting state of the electronic component in the workpiece; supplying the workpiece to a resin sealing mold; supplying a resin material to the resin sealing mold; and sealing the electronic component by compression molding the resin material on the workpiece with resin by the resin sealing mold. The resin material includes a first resin and a second resin, the first resin is a sheet-like resin, and the second resin is a granulated resin, a powdered resin, or a liquid resin. A supply amount of at least the second resin among the first resin and the second resin is determined for each workpiece based on the resin amount of the resin material calculated for each workpiece.

According to this aspect, the resin amount of the resin material to be supplied to the workpiece is calculated for each workpiece according to the mounting state of the workpiece, and the supply amount of the second resin is determined for each workpiece based on the calculated resin amount. Thus, for example, while supplying the first resin to the workpiece, the remaining resin amount may be adjusted to an appropriate amount by the second resin. As a result, an appropriate amount of resin may be supplied to each workpiece while eliminating waste of the resin supplied.

### Effects of Invention

According to the present invention, an appropriate amount of resin may be supplied to each workpiece while eliminating waste of the resin supplied.

### BRIEF DESCRIPTION OF DRAWINGS

FIG. 1 is a plan view of the resin sealing device according to one embodiment of the present invention.

FIG. 2 is a partially enlarged view of the resin sealing device in FIG. 1.

FIG. 3 is a cross-sectional view of the resin sealing mold of FIG. 1.

FIG. 4 is a flow chart illustrating the resin sealing method according to one embodiment of the present invention.

FIG. 5 is a diagram illustrating the resin sealing method according to one embodiment of the present invention.

FIG. 6 is a diagram illustrating the resin sealing method according to one embodiment of the present invention.

FIG. 7 is a diagram illustrating the resin sealing method according to one embodiment of the present invention.

FIG. 8 is a diagram illustrating the resin sealing method according to one embodiment of the present invention.

FIG. 9 is a diagram illustrating the resin sealing method according to one embodiment of the present invention.

FIG. 10 is a diagram illustrating the resin sealing method according to another embodiment of the present invention.

FIG. 11 is a diagram illustrating the resin sealing method according to another embodiment of the present invention.

FIG. 12A is a diagram illustrating the resin sealing method according to another embodiment of the present invention.

FIG. 12B is a diagram illustrating the resin sealing method according to another embodiment of the present invention.

FIG. 12C is a diagram illustrating the resin sealing method according to another embodiment of the present invention.

FIG. 12D is a diagram illustrating the resin sealing method according to another embodiment of the present invention.

FIG. 13A is a diagram illustrating the resin sealing method according to another embodiment of the present invention.

FIG. 13B is a diagram illustrating the resin sealing method according to another embodiment of the present invention.

FIG. 14A is a diagram illustrating the resin sealing method according to another embodiment of the present invention.

FIG. 14B is a diagram illustrating the resin sealing method according to another embodiment of the present invention.

### DESCRIPTION OF EMBODIMENTS

Hereinafter, the embodiments of the present invention are described with reference to the drawings. The drawings of this embodiment are illustrative, the dimensions and shapes of each part are schematic, and the technical range of the present invention should not be interpreted as being limited to the embodiment.

### First Embodiment

### <Resin Sealing Device>

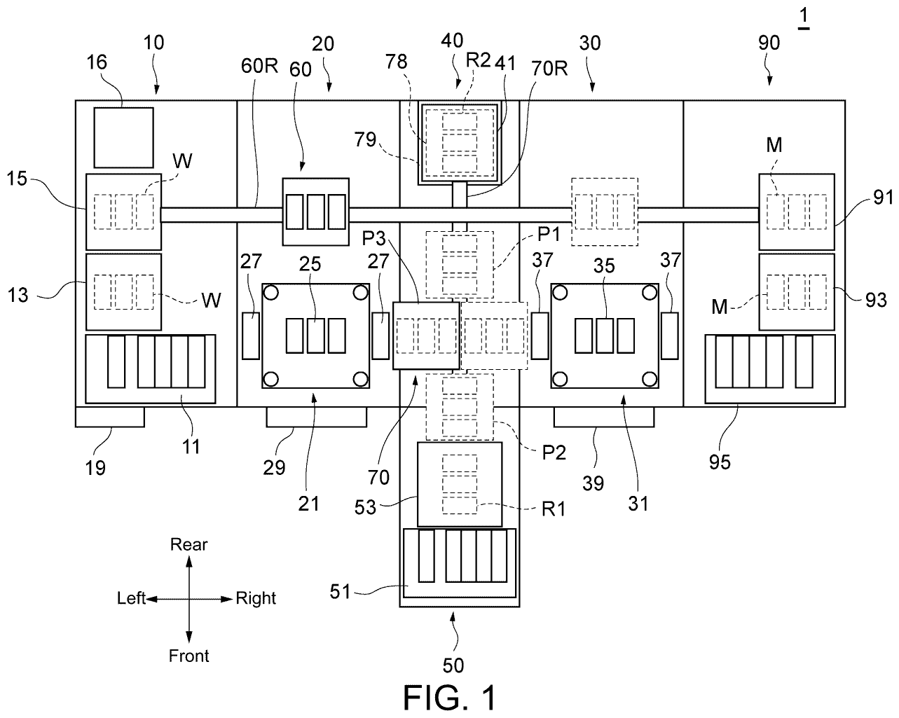

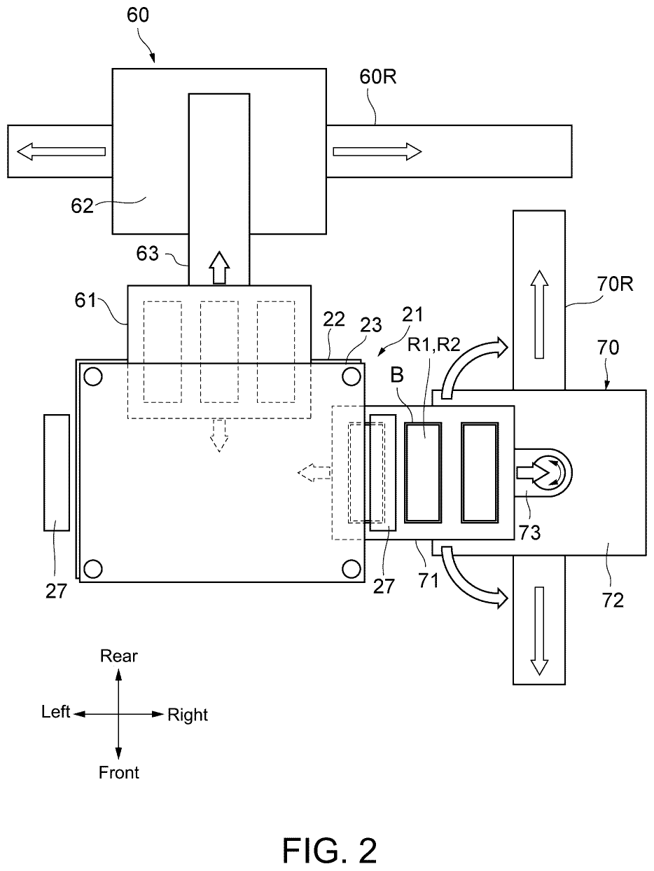

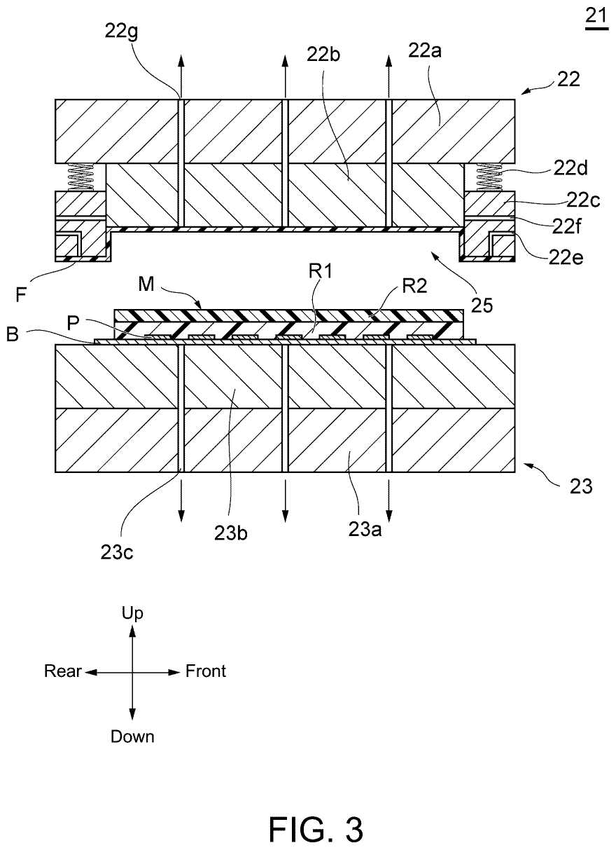

The configuration of the resin sealing device 1 according to the embodiment of the present invention is described with reference to FIG. 1 to FIG. 3. FIG. 1 is a plan view of the resin sealing device according to this embodiment. FIG. 2 is a partially enlarged view of the resin sealing device, and FIG. 3 is a cross-sectional view of the resin sealing mold. In addition, in each of FIG. 1 to FIG. 3, directions such as front, rear, left, right, up, and down are conveniently indicated in order to clarify the relationship between the drawings and to aid in understanding the positional relationship of each member.

The resin sealing device 1 is a manufacturing device that provides resin in a workpiece W and manufactures a molded product M. The workpiece W includes a substrate B and an electronic component P. The molded product M may be produced by molding resin onto the workpiece W and sealing the electronic component P of the workpiece W with resin. Here, the workpiece W includes a surface on which the electronic component P is placed (hereinafter referred to as the “surface of the workpiece W”) and a surface opposite to this surface (hereinafter referred to as the “back surface of the workpiece W”). The back surface of workpiece W is a surface on which the electronic component P is not mounted. Further, in the following description, the up and down relationship between the surface and the back surface of the workpiece W may be appropriately reversed depending on the structure of the resin sealing mold. Hereinafter, for convenience, the workpiece W after sealing with resin may be referred to as the molded product M. The substrate B is, for example, an interposer substrate, a lead frame, a carrier plate with an adhesive sheet, or a semiconductor substrate. The electronic component P is, for example, a semiconductor element such as an IC chip, but is not limited thereto, and may be various active elements, passive elements, MEMS devices, etc. As shown in FIG. 3, the resin is composed of a first resin R1 and a second resin R2. The first resin R1 and the second resin R2 may be resins having different properties or may be resins having the same properties. For example, the second resin R2 may have a higher releasability than the first resin R1. In this embodiment, the first resin R1 and the second resin R2 are in different conditions. Specifically. the first resin R1 is a sheet-like resin, while the second resin R2 is a granulated resin, a powdered resin, or a liquid resin. The sheet-like resin used as the first resin R1 is preferably a fixed amount of resin having a constant thickness, width, and length for each resin to be supplied. As a result, it is easy to determine how much additional resin to supply in relation to the total amount of resin required. In this embodiment, the combination of the first resin R1 and the second resin R2 is described as a combination of a sheet-like resin and a granulated resin, but is not limited to this combination. For example, the second resin R2 may be in a powder or liquid form.

The resin sealing device 1 according to this embodiment is a compression molding type (in other words, a compression type) resin sealing device. As shown in FIG. 1, the resin sealing device 1 includes a workpiece supply unit 10, resin molding units 20 and 30, a second resin supply unit 40, a first resin supply unit 50, a first loader 60, a second loader 70, and a molded product recovery unit 90. The first loader 60 is a loader that transports the workpiece W, and is configured to be movable along a first guide portion 60R. Further, the second loader 70 is a loader that transports the first resin R1 (e.g., a sheet-like resin) and the second resin R2 (e.g., a granulated resin), and is configured to be movable along the second guide portion 70R.

The planar layout of the resin sealing device 1 is not particularly limited, but in the example shown in FIG. 1. the workpiece supply unit 10, the resin molding unit 20, the second resin supply unit 40, the resin molding unit 30, and the molded product recovery unit 90 are arranged in this order from left to right in FIG. 1 along the first guide portion 60R. Further, with the first guide portion 60R as a reference, the second resin supply portion 41 is provided on the rear side, and the first resin supply unit 50 is provided on the front side. The first resin supply unit 50 and the second resin supply unit 40 are arranged in this order from the front to the rear in FIG. 1 along the second guide portion 70R. Further, with the second guide portion 70R as a reference, the workpiece supply unit 10 and the resin molding unit 20 are provided on the left side, and the resin molding unit 30 and the molded product recovery unit 90 are provided on the right side.

The workpiece supply unit 10 supplies the workpiece W to a first loader hand 61 of the first loader 60. The workpiece supply unit 10 includes a workpiece housing portion 11, a workpiece delivery portion 13, a workpiece preheating portion 15, and a workpiece supply control panel 19. Further, for example, the workpiece supply control panel 19 may include a display portion that displays control parameters of the molded product recovery unit 90, the second resin supply unit 40, the first resin supply unit 50, the first loader 60, and the second loader 70, and an input portion for inputting the control parameters, which is described later.

The workpiece housing portion 11 houses a plurality of workpiece W and sends out the workpiece W in sequence. For example, the workpiece housing portion 11 includes a plurality of workpiece magazines and a workpiece elevation. In the workpiece magazines set in the workpiece housing portion 11, a plurality of workpieces W are housed so as to be stacked in an up and down direction. The workpiece elevation adjusts the positions of the workpiece magazines so as to send out the workpiece W to the workpiece delivery portion 13.

The workpiece delivery portion 13 delivers the workpiece W received from the workpiece housing portion 11 to the workpiece preheating portion 15. For example, the workpiece delivery portion 13 includes a workpiece index that receives and aligns the workpiece W sent out by the workpiece housing portion 11, and a workpiece pick-and-place that sends out the workpiece W aligned by the workpiece index to the workpiece preheating portion 15.

The workpiece preheating portion 15 preheats the workpiece W received from the workpiece delivery portion 13 and delivers the same to the first loader hand 61 of the first loader 60. By preheating the workpiece W before being transport to the resin molding units 20 and 30, deformation of the workpiece W due to a sudden temperature change inside the resin sealing molds 21 and 31 may be suppressed. For example, the workpiece preheating portion 15 includes a preheat rail that heats the workpiece W from the end. Alternatively, the workpiece preheating portion 15 may include a hot plate that heats the entire surface of the workpiece W. It is noted that the workpiece preheating portion 15 may not be provided, and the workpiece W may not be preheated. In this case, after the workpiece W is transported to the resin molding units 20 and 30, the time until the start of carrying the first resin R1 and the second resin R2 into the resin molding units 20 and 30 or the start of mold closing may be controlled.

The workpiece supply control panel 19 controls the operation of the workpiece supply unit 10. When viewed from above as shown in FIG. 1, the workpiece supply control panel 19 is provided on the front surface of the workpiece supply unit 10. For example, the workpiece supply control panel 19 includes a display portion that displays the control parameters of the workpiece supply unit 10 and an input portion for inputting the control parameters of the workpiece supply unit 10.

It is noted that, the workpiece supply unit 10 includes a workpiece mounting state measuring portion 16 that measures the mounting state of the electronic component P in the workpiece W. For example, a volume measuring portion for measuring the mounting state of the electronic component P from the volume of the workpiece W, a weight measuring portion for measuring the mounting state of the electronic component P from the weight of the workpiece W, an appearance measuring portion for measuring the appearance of the workpiece W, etc. may be further provided.

The molded product recovery unit 90 recovers the molded product M from the first loader hand 61 of the first loader 60. The molded product recovery unit 90 includes a molded product receiving portion 91, a molded product delivery portion 93, and a molded product housing portion 95. In the example shown in FIG. 1, the molded product recovery unit 90 is provided on the opposite side to the workpiece supply unit 10 with respect to the resin molding units 20 and 30 in the left and right direction. Alternatively, the molded product recovery unit 90 may be provided on the same side as the workpiece supply unit 10 with respect to the resin molding units 20 and 30 in the left and right direction.

The molded product receiving portion 91 delivers the molded product M received from the first loader hand 61 of the first loader 60 to the molded product delivery portion 93. For example, the molded product receiving portion 91 includes a cooling pallet for cooling the molded product M. Further, a configuration may be adopted in which the cooling pallet is not provided and the workpiece W is not cooled.

The molded product delivery portion 93 delivers the molded product M received from the molded product receiving portion 91 to the molded product housing portion 95. For example, the molded product delivery portion 93 includes a molded product index that receives and aligns the molded product M sent out by the molded product receiving portion 91 and a molded product pick-and-place process that sends out the molded product M aligned by the molded product index to the molded product housing portion 95.

The molded product housing portion 95 receives and houses the molded product M. For example, the molded product housing portion 95 includes a plurality of molded product magazines and a molded product elevation. In the molded product magazines set in the molded product housing portion 95, a plurality of molded products M are housed so as to be stacked in an up and down direction. The molded product elevation adjusts the position of the molded product magazine so as to receive the molded product M from the molded product delivery portion 93.

It is noted that, the molded product recovery unit 90 may further include a volume measuring portion for measuring the volume of the molded product M, an appearance inspection portion for inspecting the appearance of the molded product M, etc.

The resin molding unit 20 molds the first resin R1 and the second resin R2 on the workpiece W. The resin molding unit 20 includes a resin sealing mold 21, film handlers 27, and a resin molding control panel 29.

As shown in FIG. 3, the resin sealing mold 21 includes a pair of openable and closable upper mold 22 and lower mold 23, in which the first resin R1 and the second resin R2 are filled and molded in the inner cavity 25. In the example shown in FIG. 3, the resin sealing mold 21 is a so-called upper cavity movable structure compression molding mold. Specifically, the surface of the lower mold 23 facing the upper mold 22 is flat, and a cavity 25 is formed in the surface of the upper mold 22 facing the lower mold 23. The cavity 25 is a recessed portion (an example of a cavity recessed portion) opening toward the lower mold 23.

The upper mold 22 includes an upper plate 22a, a cavity piece 22b, a clamper 22c, and an energizing member 22d. The cavity piece 22b is fixed to and assembled on the lower surface (the surface on the lower mold 23 side) of the upper plate 22a. The clamper 22c is configured in a frame shape so as to surround the cavity piece 22b. The clamper 22c is assembled to the upper plate 22a via the energizing member 22d so as to be movable in the up and down direction. The cavity piece 22b constitutes a bottom surface portion of the cavity 25, and the clamper 22c constitutes a side surface portion of the cavity 25. The upper mold 22 is provided with suction holes 22e and 22f penetrating the clamper 22c and a suction hole 22g penetrating the upper plate 22a and the cavity piece 22b. The suction hole 22e is opening on the lower surface of the clamper 22c. The suction hole 22f is opened on the inner side surface of the clamper 22c facing the cavity piece 22b. A seal member (not shown) is inserted under the suction hole 22f. The suction hole 22g is opening on the upper surface of the cavity piece 22 b, that is, on the bottom surface of the cavity 25. The suction holes 22e, 22f, and 22g are for suctioning the film F set in the upper mold 22.

The lower mold 23 includes a lower plate 23a and a cavity plate 23b. The cavity plate 23b is fixed to and assembled on the upper surface (the surface on the upper mold 22 side) of the lower plate 23a. The lower mold 23 is provided with a suction hole 23c penetrating the lower plate 23a and the cavity plate 23b. The suction hole 23c is opening on the lower surface of the cavity plate 23b. The suction hole 23c is a suction hole for suctioning the workpiece W set in the lower mold 23.

The film handlers 27 supply the film F to the resin sealing mold 21. The film F is a release film for facilitating the release of the molded product M from the upper mold 22 while preventing the first resin R1 and the second resin R2 from entering the gap in the upper mold 22 that forms the recessed portion of the cavity 25. The film handlers 27 handle, for example, a roll of film, and includes an unwinding portion that supplies unused film F and a winding portion that collects used film F. As shown in FIG. 1, the unwinding portion and the winding portion of the film handlers 27 are provided in the left and right direction of the resin sealing mold 21. As the material for the film F, a polymeric material having excellent heat resistance, ease of peeling, flexibility, and extensibility may be used, examples of such materials include PTFE (polytetrafluoroethylene), ETFE (ethylene-tetrafluoroethylene copolymer), FEP (fluorinated ethylene propylene), PET (polyethylene terephthalate), PP (polypropylene), and PVDC (polyvinylidene chloride). The thickness of the film F is appropriately selected corresponding to the physical properties of the material, and is, for example, about 50 μm. The shape of the film F is not limited to a roll, but may be a strip.

The resin molding control panel 29 controls the operation of the resin molding unit 20. When viewed from above as shown in FIG. 1, the resin molding control panel 29 is provided on the front surface of the resin molding unit 20. For example, the resin molding control panel 29 includes a display portion that displays the control parameters of the resin molding unit 20 and an input portion for inputting the control parameters of the resin molding unit 20.

The resin molding unit 30 includes a resin sealing mold 31, film handlers 37, and a resin molding control panel 39. In the following description, details of the resin sealing mold 31, the film handlers 37, and the resin molding control panel 39 are omitted, but the same configurations as those described for the resin molding unit 20 may be applied.

It is noted that at least a part of the functions of the resin molding control panels 29 and 39 may be integrated into the workpiece supply control panel 19. For example, the control parameters of the resin molding units 20 and 30 may be displayed on the display portion of the workpiece supply control panel 19, and the control parameters of the resin molding units 20 and 30 may be input to the input portion of the workpiece supply control panel 19. When all the functions of the control panels of the respective units are integrated into the workpiece supply control panel 19, the resin molding control panels 29 and 39 may be omitted.

The first resin supply unit 50 includes a first resin housing portion 51 and a first resin delivery portion 53.

The first resin housing portion 51 houses a plurality of first resins R1 and sequentially sends out the first resins R1. For example, the first resin housing portion 51 includes a plurality of magazines and an elevation. The magazine set in the first resin housing portion 51 may be a slit magazine in which a plurality of first resins R1 are housed so as to be stacked in an up and down direction, or may be a stack magazine in which a plurality of first resins R1 are housed so as to be stacked in an up and down direction. The elevation adjusts the position of the magazines so as to send out the first resin R1 to the first resin delivery portion 53.

The first resin delivery portion 53 delivers the first resin R1 received from the first resin housing portion 51 to the holding tool 78. For example, the first resin delivery portion 53 receives the second resin R2 sent out by the first resin housing portion 51, aligns the second resin R2, and sends out the same to the holding tool 78. At this time, the first resin R1 may be picked up by a chucking function provided in the holding tool 78.

It is noted that the first resin supply unit 50 may further include a volume measuring portion for measuring the volume of the first resin R1 or a weight measuring portion for measuring the weight of the first resin R1, an appearance inspection portion for inspecting the appearance of the first resin R1, or, a first resin preheating portion for preheating the first resin R1, etc.

The second resin supply unit 40 supplies granulated second resin R2 on the first resin R1. The second resin supply unit 40 includes a second resin supply portion 41 and a resin heater 80.

The second resin supply portion 41 supplies the second resin R2 onto the first resin R1 held by the holding tool 78. The second resin supply portion 41 includes a hopper 42 and a feeder 43. In addition, when the second resin is a liquid resin, the resin supply portion may include a syringe for storing the resin, a piston for pushing out the resin, and a pinch valve for opening and closing the tip of the syringe.

The resin heater 80 heats the first resin R1 and the second resin R2 supplied on the first resin R1. As the heat source of the resin heater 80, for example, a known heating mechanism such as an electric heating wire heater or an infrared heater is used. It is noted that the resin heater 80 may be omitted.

In the second resin supply unit 40, it is preferable that a resin guard 44, which is described later, is provided inside the holding tool 78. The resin guard 44 is configured in a frame shape along the outer shape of the first resin R1, and is used as a frame that defines a region in which the second resin R2 is dispersed. The resin guard 44 is, for example, attached to the holding tool 78 before the second resin R2 is supplied, and is removed from the holding tool 78 after the second resin R2 is heated. In the case that the holding tool 78 is usable as a frame that defines a region in which the resin R is dispersed, the resin guard 44 may be omitted.

In addition, the second resin supply unit 40 includes a resin amount calculation portion 79. The resin amount calculation portion 79, the resin amount calculation portion 79 calculates and sets the resin amount to be supplied based on the mounting state of each workpiece acquired in the workpiece mounting state measuring portion 16. Specifically, as an index of the mounting state, the total resin amount required for one resin-sealing may be calculated based on the number of chips mounted on the workpiece and the chip stack height, and the supply amount of the second resin R2 may be determined based on that resin amount and the resin amount of the first resin R1. At this time, the supply amount of the first resin R1 may be determined by the volume or weight, etc., grasped in advance by using a fixed amount of resin sheet-like resin with constant thickness, width, and length, or the supply amount thereof may be determined by measuring the volume or the like of the first resin R1. The supply amount of the second resin R2 may be determined based on the difference between the resin amount calculated by the resin amount calculation portion 79 and the supply amount of the first resin R1. In addition, the supply amount of the first resin R1 is based on the resin amount required when all the electronic components P are mounted. In this embodiment, the resin is supplied using the first resin R1 and the second resin R2, but it is also possible to supply only the first resin R1. In addition, the supply amount of the second resin R2 may be smaller than the supply amount of the first resin R1. In this case, by adjusting the supply amount of the second resin R2 to make up for the shortage, an appropriate amount of resin may be supplied to each workpiece while eliminating waste of the resin supplied. It is noted that the supply amount of the second resin R2 is determined by the resin amount to compensate for the shortage of the volume of the electronic component P. Thus, depending on the proportion of the electronic component P in the cavity, the supply amount of the second resin R2 may be adjusted to be greater than or equal to the supply amount of the first resin R1. Further, when the number of workpieces on which the electronic component P is mounted does not reach the specified number, a workpiece on which the electronic component P is not mounted (i.e., a dummy workpiece) may be added, and in that case, the second resin R2 is supplied up to the maximum supply amount.

It is noted that the second resin supply unit 40 may further include a weight measuring portion for measuring the weight of the second resin R2, a vibration portion for dispersing the second resin R2 by vibration, and an inspection portion for inspecting the degree of dispersion of the second resin R2.

The first loader 60 transports the workpiece W from the workpiece supply unit 10 to the resin molding units 20 and 30. The first loader 60 is configured to be movable along the first guide portion 60R. The first guide portion 60R extends in the left and right direction across the workpiece supply unit 10, the resin molding units 20 and 30, the second resin supply unit 40, and the molded product recovery unit 90. When viewed from above as shown in FIG. 1, the first guide portion 60R is provided, for example, behind the resin sealing molds 21 and 31 and on the front side of the second resin supply portion 41. In the configuration example shown in FIG. 1, the first loader 60 transports the molded product M from the resin molding units 20 and 30 to the molded product recovery unit 90.

As shown in FIG. 2, the first loader 60 includes a first loader hand 61, a first base 62, and a first guide rod 63.

The first loader hand 61 is configured to be able to advance and retreat from the rear side of the resin sealing mold 21. In other words, the first loader hand 61 has a transport path for the workpiece W or the molded product M (an example of the workpiece) on the rear side of the resin sealing mold 21. The first loader hand 61 holds a workpiece W or a molded product M. The first loader hand 61 has, for example, an L-shaped opening and closing claw that supports the lower surface of the workpiece W or the molded product M, but is not limited thereto. The first loader hand 61 may suck the workpiece W or the molded product M by electrostatic force, or may suck the workpiece W or the molded product M by suction and exhaust.

As shown in FIG. 2, the first base 62 is connected to the first guide portion 60R so as to be movable in the left and right direction.

As shown in FIG. 2, the first guide rod 63 is connected to the first base 62 and supports the first loader hand 61. The first guide rod 63 is configured to be extendable and retractable in the front and rear direction, and moves the first loader hand 61 in the front and rear direction.

As an example, after receiving the workpiece W at the workpiece delivery portion 13. the first loader hand 61 is transported to the right by the first base 62 and moves to a position facing the resin sealing mold 21 in the front and rear direction. Next, the first loader hand 61, while still holding the workpiece W, enters the resin sealing mold 21 from the rear side due to the extension of the first guide rod 63. That is, the first loader hand 61 carries the workpiece W into the resin sealing mold 21. After delivering the workpiece W to the lower mold 23 of the resin sealing mold 21, the first loader hand 61 moves to the rear side of the resin sealing mold 21 due to the contraction of the first guide rod 63. After the molded product M is molded and the resin sealing mold 21 is opened, the first loader hand 61 carries the molded product M out of the resin sealing mold 21 by the same operation as when the workpiece W is carried in. Then, the first loader hand 61 is transported to the right by the first base 62 and delivers the molded product M to the molded product receiving portion 91.

The second loader 70 transports the first resin R1 and the second resin R2. The second loader 70 is configured to be movable along the second guide portion 70R. The second guide portion 70R is provided, for example, in the second resin supply unit 40 and extends in the front and rear direction. When viewed from above as shown in FIG. 1, the second guide portion 70R intersects with, for example, the first guide portion 60R.

As shown in FIG. 2, the second loader 70 includes a second loader hand 71, a second base 72, and a second guide rod 73.

As shown in FIG. 2, the second base 72 is configured to be movable in the front and rear direction with respect to the second guide portion 70R, but is not limited to movement in the front and rear direction and may be configured to be movable in the left and right direction.

As shown in FIG. 2, the second guide rod 73 is connected to the second base 72 and supports the second loader hand 71. The second guide rod 73 is configured to be extendable and rotatable from the point where it is connected to the second base 72. As a result, the second guide rod 73 moves the second loader hand 71 in a forward/backward or left/right direction, and rotates the second loader hand 71 around the second base 72.

As an example, the second loader hand 71 transports the holding tool 78 to the first resin delivery portion 53. After receiving the first resin R1 by the holding tool 78 at the first resin delivery portion 53, the second loader hand 71 is transported to the rear side by the second base 72 and transports the first resin R1 via the holding tool 78 to a position P2 on the rear side of the first resin delivery portion 53. Next, the second loader hand 71 moves to a position P1 on the front side of the second resin supply portion 41 due to the rotation of the second guide rod 73. Next, the second loader hand 71 moves to the second resin supply portion 41 due to the extension of the second guide rod 73. In the second resin supply portion 41, the second loader hand 71 releases the holding tool 78. The resin guard 44 is set inside the released holding tool 78. Then, after the second resin R2 is received on the first resin R1 and inside the resin guard 44, the first resin R1 and the second resin R2 are heated, and after heating, the resin guard 44 is removed. Thereafter, the second loader hand 71 again picks up the holding tool 78, and returns to position P1 due to the contraction of the second guide rod 73. Next, the second loader hand 71 moves to a position P3 to the right of the resin sealing mold 21 due to the rotation of the second guide rod 73. Next, the second loader hand 71, while holding the first resin R1 and the second resin R2 via the holding tool 78, enters the resin sealing mold 21 from the right due to the extension of the second guide rod 73. That is, the second loader hand 71 carries the first resin R1 and the second resin R2 into the resin sealing mold 21 via the holding tool 78. After delivering the first resin R1 and the second resin R2 to the resin sealing mold 21, the second loader hand 71 moves to the right of the resin sealing mold 21 due to the contraction of the second guide rod 73.

In this way, in the case that the second loader hand 71 is movable from the second resin supply unit 40 to the first resin delivery portion 53 due to the extension and contraction of the second guide rod 73, the first resin supply unit 50 may be added without extending the second guide portion 70R to the first resin supply unit 50.

The first loader 60 and the second loader 70 operate for the resin sealing mold 31 of the resin molding unit 30 in the same manner as they operate for the resin sealing mold 21 of the resin molding unit 20. Thus, the description of the operation of the first loader 60 and the second loader 70 for the resin sealing mold 31 is omitted. However, the operation of the second loader 70 with respect to the resin sealing mold 31 is the left-right inverse of the operation of the second loader 70 with respect to the resin sealing mold 21.

Next, a transport path when the first loader hand 61 supplies the workpiece to the resin sealing mold 21 is described. The first loader hand 61 receives the workpiece W at the workpiece preheating portion 15. Alternatively, the workpiece preheating portion 15 may be configured to be movable along the first guide portion 60R. At this time, the movement of the first loader 60 in the left and right direction is restricted. Thereafter, the first loader 60, with the first loader hand 61 holding the workpiece W, moves in the right direction along the first guide portion 60R and transports the workpiece W to the rear side of the resin sealing mold 21. Thereafter, as shown in FIG. 2, the first loader hand 61 and the workpiece W are transported to the resin sealing mold 21 due to the extension and contraction of the first guide rod 63, and the workpiece W is placed on the resin sealing mold 21 by the first loader hand 61. After the sealing with resin is performed in the resin sealing mold 21, while the workpiece W is held by the first loader hand 61, the workpiece W is withdrawn from the resin sealing mold 21 due to the extension and contraction of the first guide rod 63.

On the other hand, the transport path when the first loader hand 61 removes the workpiece from the resin sealing mold 21 is described. As shown in FIG. 2, the first loader hand 61 is transported to the resin sealing mold 21 due to the extension and contraction of the first guide rod 63, and the workpiece W is withdrawn from the resin sealing mold 21 due to the extension and contraction of the first guide rod 63 while being held by the first loader hand 61. Thereafter, the first loader 60, with the first loader hand 61 holding the workpiece W, moves in the right direction along the first guide portion 60 R and delivers the workpiece W to the molded product receiving portion 91. Alternatively, the molded product receiving portion 91 may be configured to be movable along the first guide portion 60R. At this time, the movement of the first loader 60 in the left and right direction is restricted. The above-mentioned transport path for supplying or removing the workpiece W is also the same for the resin sealing mold 31.

In this embodiment, the first loader hand 61 transports the workpiece W, and the second loader hand 71 transports the first resin R1 and the second resin R2 as described above, but the present invention is not limited thereto. For example, one loader hand may simultaneously transport the workpiece and the resin, or may transport one of the workpiece and the resin and then the other.

In the example shown in FIG. 1 and FIG. 2, the transport path of the first loader hand 61 is positioned at the rear side of the resin sealing molds 21 and 31, but is not limited to this aspect. For example, a first loader hand may be provided on the rear side of the resin sealing mold 21, and another first loader hand may be provided on the rear side of the resin sealing mold 31.

The second resin R2 preferably has a higher releasability than the first resin R1. In this case, the second loader hand 71 transports the first resin, with the second resin placed on top thereof, to the resin sealing mold 21. Thereafter, the second resin R2 is pressed and placed into the recessed portion of the cavity 25. According to this aspect, the high releasability allows the resin to be easily released from the film F after molding.

As described above, according to the resin sealing device described in this embodiment, the amount of resin material may be adjusted according to the mounting state of the workpiece. Thus, a resin sealing device that may supply an appropriate amount of resin to each workpiece while eliminating waste of the resin supplied may be provided.

### <Resin Sealing Method>

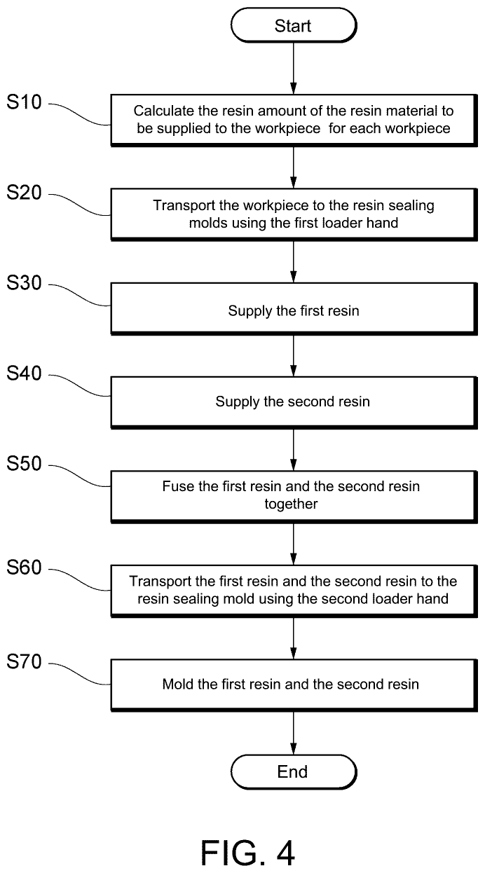

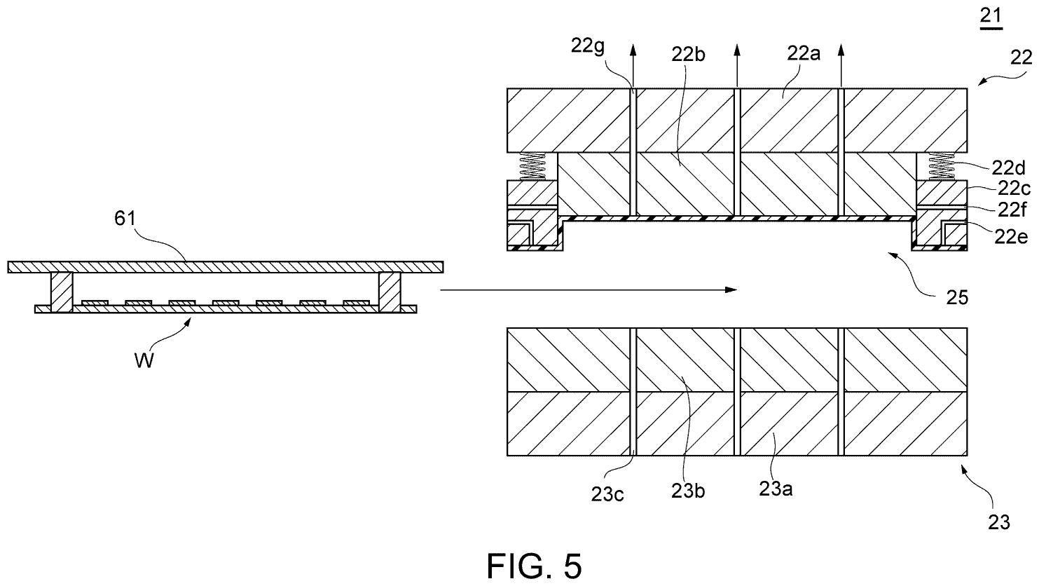

Next, the resin sealing method is described with reference to FIG. 4 to FIG. 9. FIG. 4 is a flow chart illustrating one example of the resin sealing method using the resin sealing device according to this embodiment. FIG. 5 to FIG. 9 are diagrams illustrating the resin sealing method according to this embodiment. In the following description, a method using a resin sealing device having a cavity in an upper mold is described. Here, the resin sealing mold 21 of the resin molding unit 20 is described as an example, and a description of the resin sealing mold 31 of the resin molding unit 30, which operates in the same manner, is omitted.

First, the resin amount of the resin material to be supplied to the workpiece W is calculated for each workpiece (S10).

Specifically, the workpiece supply unit 10 in FIG. 1 includes a workpiece mounting state measuring portion 16 for measuring the mounting state of the electronic components P on the workpiece W, and the resin amount to be supplied may be calculated by a volume measuring portion for measuring the mounting state of the electronic component P from the volume of the workpiece W, a weight measuring portion for measuring the mounting state of the electronic component P from the weight of the workpiece W, an appearance inspection portion for inspecting the appearance of the workpiece W, etc. Alternatively, the resin amount to be supplied may be calculated using data obtained by measuring the mounting state in advance. The resin amount of the second resin R2 to be supplied may be calculated in the resin amount calculation portion 79 based on the mounting state obtained by the workpiece mounting state measuring portion 16.

Next, the first loader hand 61 supplies the workpiece W to the resin sealing molds 21 and 31 (S20).

Specifically, the workpiece W received from the workpiece delivery portion 13 in FIG. 1 is preheated in the workpiece preheating portion 15 and held in the first loader hand 61 of the first loader 60. Thereafter, the first loader hand 61 moves to the resin molding unit 20 while holding the workpiece W as shown in FIG. 5. Before and after this step, the film F is moved to the cavity 25 provided on the upper mold 22 side. After the film F is moved, the film F is sucked by the suction hole 22g and set in the cavity 25.

Next, the first resin R1 is supplied (S30).

Specifically, the first resin R1 housed in the first resin housing portion 51 is delivered to the first resin delivery portion 53. Thereafter, the first resin delivery portion 53 delivers the first resin R1 received from the first resin housing portion 51 to the holding tool 78. At this time, the supply amount of the first resin may be constant, or the supply amount may be adjusted based on the mounting state obtained in the workpiece mounting state measuring portion 16. Alternatively, the supply amount may be adjusted using data obtained by measuring the mounting state in advance. Also, a first resin R1 for a workpiece on which no electronic component P is mounted (i.e., a dummy workpiece) may be prepared. Thereafter, the holding tool 78, while holding the first resin R1, is picked up by the second loader hand 71 and transported to the second resin supply unit 40.

Next, the second resin R2 is supplied (S40).

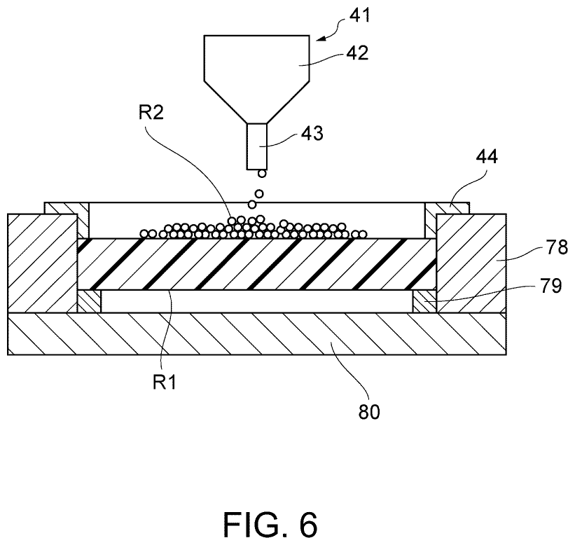

Specifically, the first resin R1 transported by the second loader hand 71 is transported to the second resin supply portion 41. Thereafter, as shown in FIG. 6, a resin guard 44 is provided on the first resin R1, and the second resin R2 is supplied. At this time, the supply amount of the second resin is adjusted based on the mounting state obtained in the workpiece mounting state measuring portion 16. As an index of the mounting state at this time, the resin amount required for one resin-sealing may be calculated based on the number of chips mounted in the workpiece and the chip stack height, and the supply amount of the second resin R2 may be determined.

Next, the first resin R1 and the second resin R2 are fused together (S50).

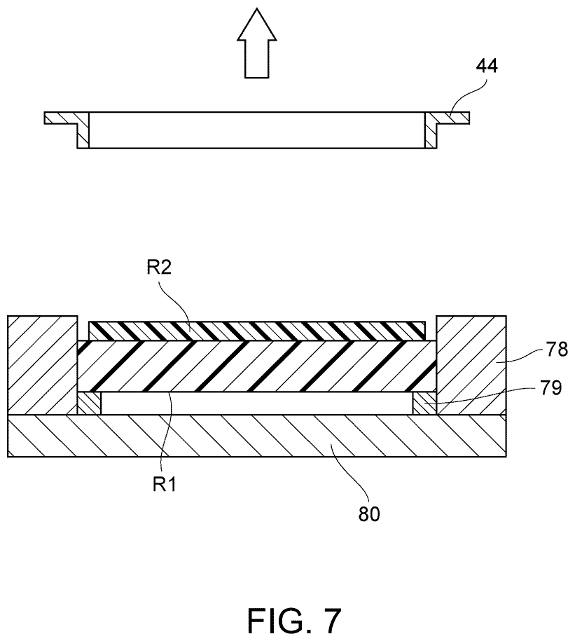

Specifically, the first resin R1 and the second resin R2 are heated by the resin heater 80. The resin heater 80 may heat the second resin R2 from above. The heating temperature of the resin is preferably 90° C. or less. After the resin is heated, the resin guard 44 is removed as shown in FIG. 7. In this embodiment, an example in which the first resin R1 and the second resin R2 are fused together in S50 has been described, but the present invention is not limited thereto, and the transport process described below may be performed without necessarily fusing the resins together.

Next, the first resin R1 and the second resin R2 are transported by the second loader hand 71 to the resin sealing mold 21 (S60).

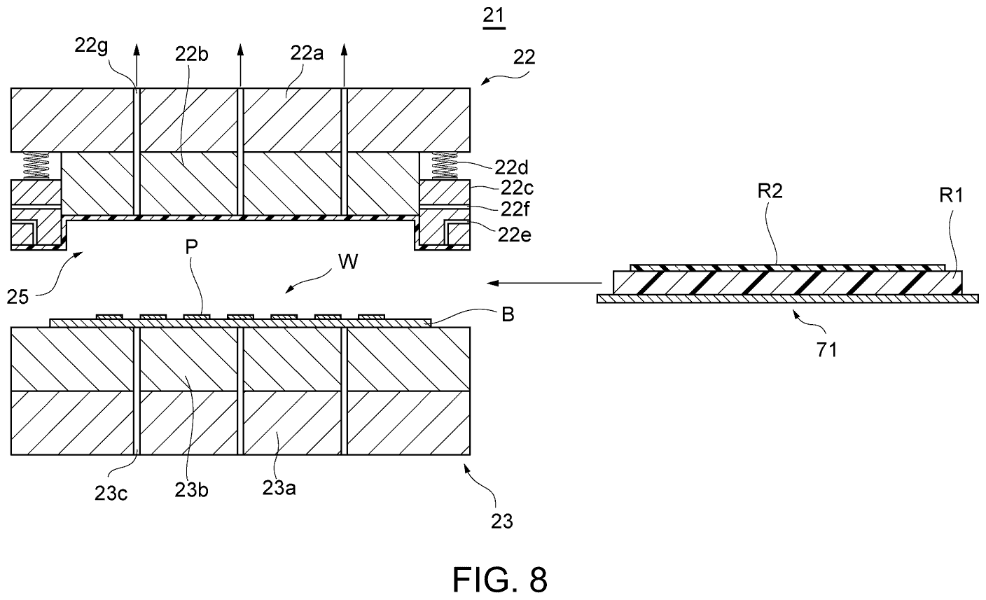

Specifically, as shown in FIG. 8, the first resin R1 and the second resin R2 are transported to the resin sealing mold 21 while being placed on the second loader hand 71.

Next, the first resin R1 and the second resin R2 are molded (S70).

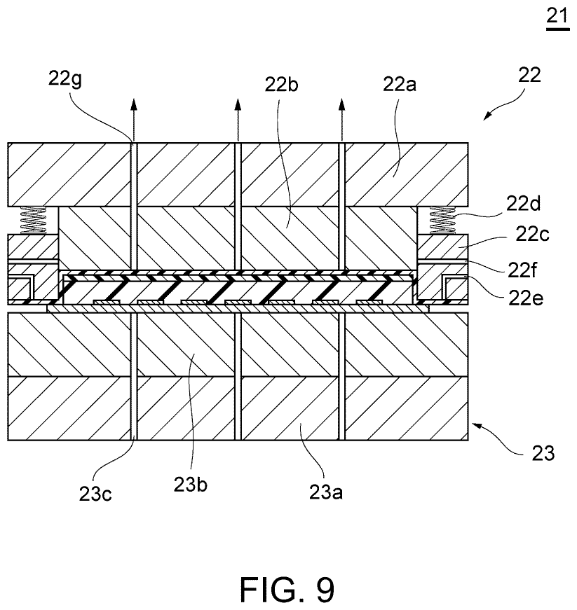

Specifically, as shown in FIG. 9, the resin sealing mold 21 is clamped, and the first resin R1 and the second resin R2 are heated while being pressurized by the upper mold 22 and the lower mold 23. Once the first resin R1 and the second resin R2 have hardened, the mold is opened.

As described above, according to the resin sealing method described in this embodiment, the amount of resin material may be adjusted according to the mounting states of the workpiece. Thus, a resin sealing method may be provided that may supply an appropriate amount of resin to each workpiece while eliminating waste of the resin supplied.

### Second embodiment

### <Resin Sealing Device>

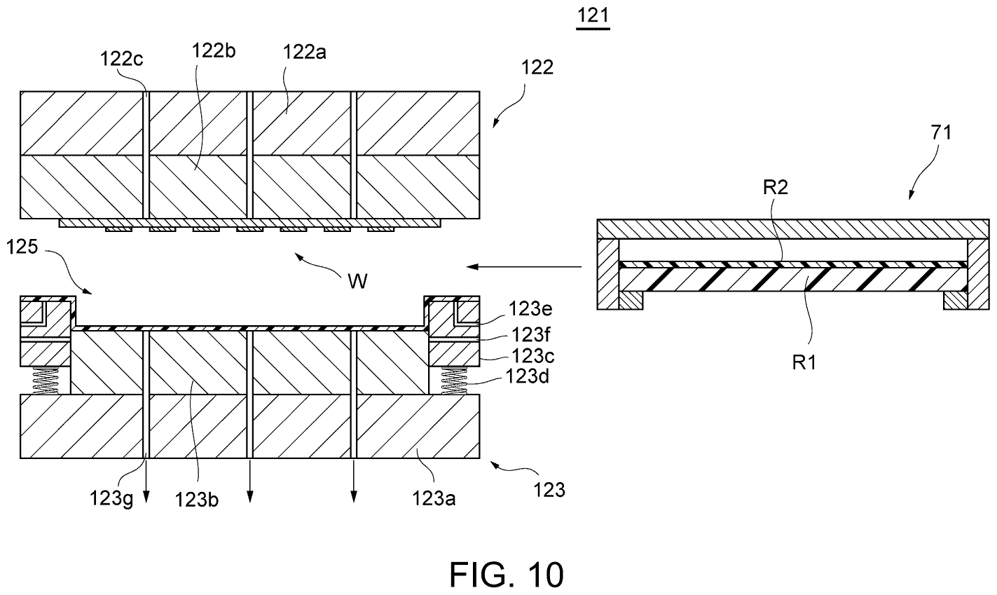

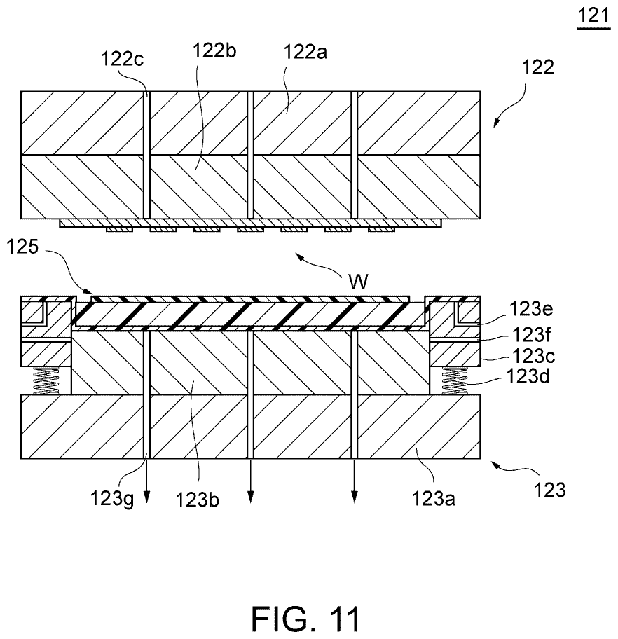

Next, the structure of the resin sealing mold 121 according to the second embodiment is described with reference to FIG. 10 to FIG. 11.

In this embodiment, unlike the first embodiment, a cavity 125 is provided on the lower mold 123 side. The resin sealing mold 21 is a pair of openable and closable molds, in which the first resin R1 and the second resin R2 are filled and molded in the inner cavity 125. The resin sealing mold 121 includes an upper mold 122 and a lower mold 123. The surface of the lower mold 123 facing the upper mold 122 is flat, and a cavity 125 is formed in the surface of the upper mold 122 facing the lower mold 123. That is, the resin sealing mold 121 is a so-called lower cavity movable structure compression molding mold. The cavity 125 is a recessed portion that opens toward the lower mold 123 and corresponds to an example of a “cavity recessed portion” according to the present invention.

The upper mold 122 includes an upper plate 122a and a cavity plate 122b. The cavity plate 122b is fixed to and assembled on the lower surface (the surface on the lower mold 123 side) of the upper plate 122a. The upper mold 122 is provided with a suction hole 122c penetrating the upper plate 122a and the cavity plate 122b. The suction hole 122c is opening on the lower surface of the cavity plate 122b. The suction hole 122c is a suction hole for suctioning the workpiece W set in the upper mold 122.

The lower mold 123 includes a lower plate 123a, a cavity piece 123b, a clamper 123c, and an energizing member 123d. The cavity piece 123b is fixed to and assembled on the top surface (the surface on the upper mold 122 side) of the lower plate 123a. The clamper 123c is configured in a frame shape so as to surround the cavity piece 123b. The clamper 123c is assembled to the lower plate 123a via the energizing member 123d so as to be movable in the up and down direction. The cavity piece 123b constitutes a bottom surface portion of the cavity 125, and the clamper 123c constitutes a side surface portion of the cavity 125. The lower mold 123 is provided with suction holes 123e and 123f penetrating the clamper 123c and a suction hole 123g penetrating the lower plate 123a and the cavity piece 123b. The suction hole 123e is opening on the upper surface of the clamper 123c. The suction hole 123f is opened on the inner side surface of the clamper 123c facing the cavity piece 123b. A seal member (not shown) is inserted under the suction hole 123f. The suction hole 123g is opening on the upper surface of the cavity piece 123b, that is, on the bottom surface of the cavity 125. The suction holes 123e, 123f, and 123g are for suctioning the film F set in the lower mold 123.

The first resin R1 preferably has a higher releasability than the second resin R2. In this case, the second loader hand 71 transports the first resin, with the second resin placed on top thereof, to the resin sealing mold 21. Then, the first resin R1 is pressed and placed into the recessed portion of the cavity 25. According to this aspect, the high releasability allows the resin to be easily released from the film F after molding.

By using such a resin sealing mold, compression molding of a lower cavity movable structure having a cavity 125 on the lower mold 123 side may be performed. Furthermore, the amount of resin material may be adjusted corresponding to the mounting state of the workpiece. Thus, a resin sealing device that may supply an appropriate amount of resin to each workpiece while eliminating waste of the resin supplied may be provided.

### <Resin Sealing Method>

Next, a resin sealing method using the resin sealing mold 121 according to the second embodiment is described with reference to FIG. 10 to FIG. 11. FIG. 10 to FIG. 11 are diagrams illustrating the resin sealing method according to this embodiment. In the following description, a method using a resin sealing device having a cavity in a lower mold is described. The resin sealing mold 121 of this embodiment includes a cavity 125 in a lower mold 123. Thus, unlike the first embodiment in which the workpiece W is placed on the lower mold 23, in this embodiment the workpiece W is placed on the upper mold 122.

As shown in FIG. 10, the second loader hand 71 enters the resin sealing mold 121 while holding the first resin R1 and the second resin R2. As shown in FIG. 11, the first resin R1 and the second resin R2 are set in the cavity 125 provided in the lower mold 123.

### Modified Example

A modified example different from the above embodiment is described.

### First Modified Example

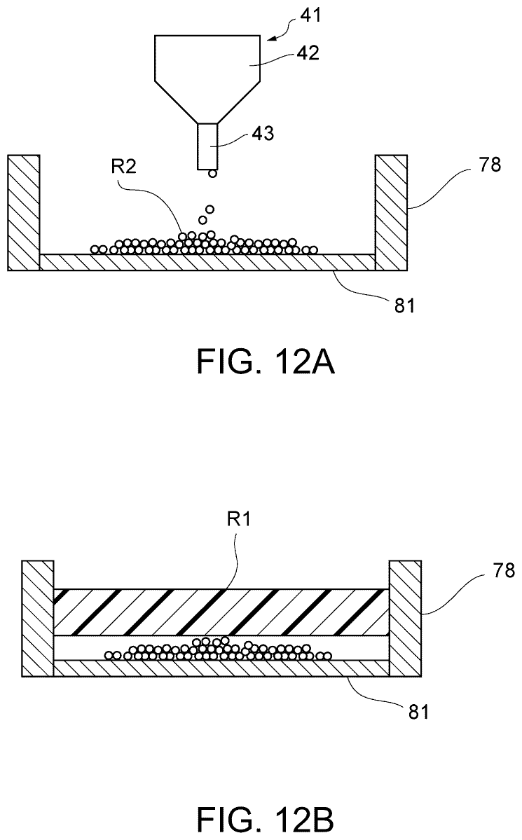

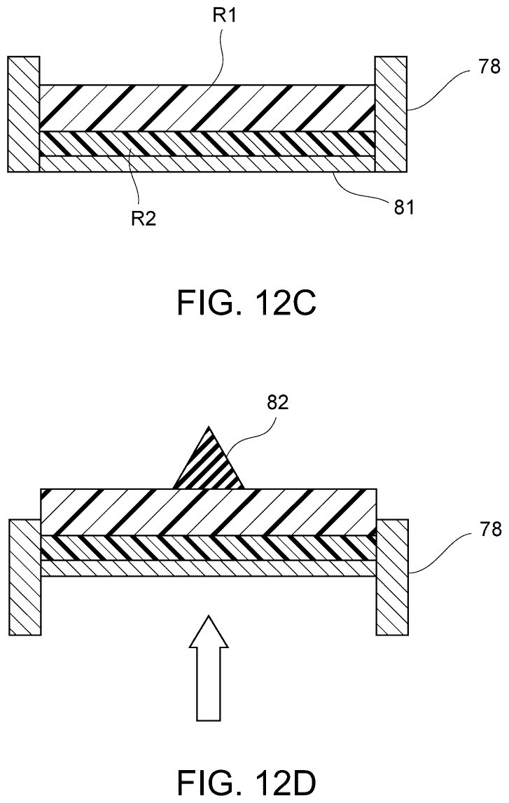

In the above embodiment, the second resin R2 is supplied on the upper portion of the first resin R1, but the upper and lower portion may be reversed. That is, the first resin may be supplied on the upper portion of the second resin. Specifically, as shown in FIG. 12A, the second resin R2 is supplied to a region surrounded by a holding tool 78 and a plunger 81. Next, as shown in FIG. 12B, a first resin R1 is supplied on upper portion of the second resin R2. Next, as shown in FIG. 12C, the first resin R1 and the second resin R2 are heated and fused together. Next, as shown in FIG. 12D, the first resin R1 is pushed up by the plunger 81 while being sucked by the suction pad 82 from the upper portion. Thereafter, the first resin R1 and the second resin R2 are transported to the resin sealing mold 121. The adsorption pad 82 may be an electrostatic chuck.

### Second Modified Example

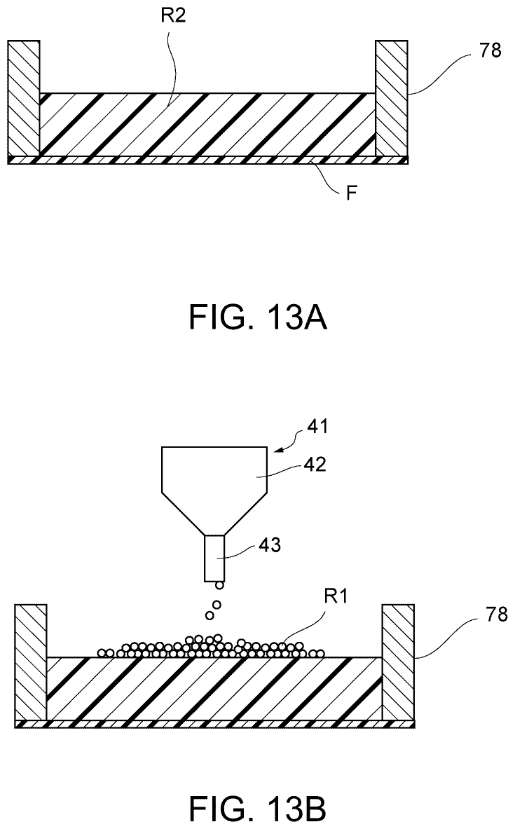

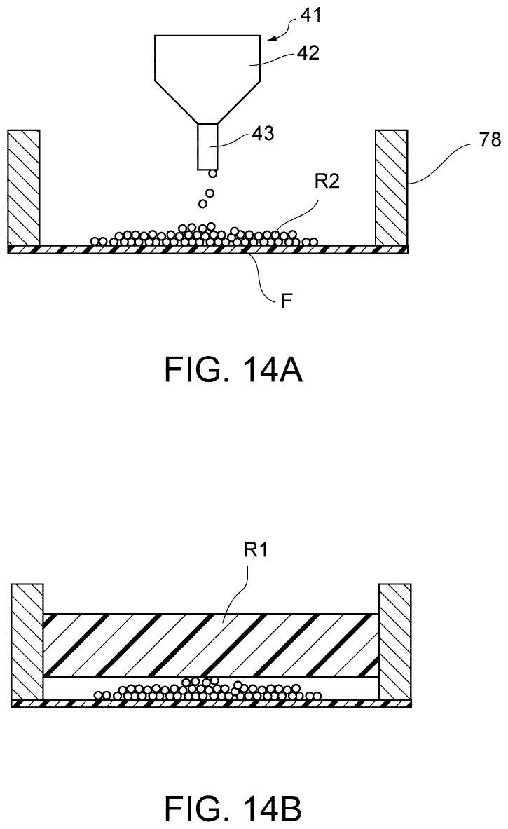

When a sheet of film is used as the film, as shown in FIG. 13A, the first resin R1 is supplied to a region surrounded by the sheet of film and the holding tool 78. Then, as shown in FIG. 13B, the second resin R2 is supplied to the upper portion of the first resin R1. In this modified example, the second resin R2 may be supplied as shown in FIG. 14A, and then the first resin R1 may be supplied as shown in FIG. 14B.

As described above, the resin sealing device according to one aspect of the present invention is a compression molding type resin sealing device configured to seal an electronic component of a workpiece including a substrate and the electronic component with resin, and the resin sealing device includes: a resin sealing mold, configured to seal the electronic component with rein by compression molding a resin material on the workpiece; and a resin amount calculation portion 79, configured to calculate, for each workpiece, a resin amount of the resin material to be supplied to the workpiece based on a mounting state of the electronic component in the workpiece. The resin material includes a first resin and a second resin, the first resin is a sheet-like resin, the second resin is a granulated resin, a powdered resin, or a liquid resin, and a supply amount of at least the second resin among the first resin and the second resin is determined for each workpiece based on the resin amount calculated by the resin amount calculation portion 79.

As a result, the amount of resin material may be adjusted according to the mounting state of the workpiece. Thus, a resin sealing device that may supply an appropriate amount of resin to each workpiece while eliminating waste of the resin supplied may be provided.

In the above aspect, the second resin is a resin having identical or different properties as the first resin.

In the above aspect, a first resin supply portion configured to supply the first resin and a second resin supply portion configured to supply the second resin are provided. The second resin supply portion is configured to supply the second resin into an opening of a guide portion on the first resin supplied by the first resin supply portion.

In the above aspect, the resin sealing mold includes an upper mold and a lower mold, and the upper mold has a cavity recessed portion opening toward the lower mold.

In the above aspect, a loader hand configured to transport the resin material to the resin sealing mold is further provided. The second resin has a higher releasability than the first resin, and the loader hand is configured to provide the first resin and the second resin in the cavity recessed portion with the second resin facing the upper mold.

In the above aspect, the resin sealing mold includes an upper mold and a lower mold, and the lower mold has a cavity recessed portion opening toward the upper mold.

In the above aspect, a loader hand configured to transport the resin material to the resin sealing mold is further provided. The first resin has a higher releasability than the second resin, and the loader hand is configured to provide the first resin and the second resin in the cavity recessed portion with the first resin facing the lower mold.

In the above aspect, a first resin supply portion configured to supply the first resin and a second resin supply portion configured to supply the second resin are provided. The second resin supply portion is configured to supply the second resin into an opening of a guide portion, and the first resin supply portion is configured to supply the first resin on the second resin.

In the above aspect, a loader hand configured to transport the resin material to the resin sealing mold is further provided. The loader hand has a suction pad or an electrostatic chuck.

In the above aspect, a loader hand configured to transport the resin material to the resin sealing mold is further provided. The loader hand is configured to transport the first resin and the second resin to the resin sealing mold in a state in which the first resin and the second resin are fused together.

In the above aspect, a supply amount of the second resin is determined based on a difference between the resin amount calculated by the resin amount calculation portion and a supply amount of the first resin.

In the above aspect, a supply amount of the second resin is smaller than a supply amount of the first resin. The supply amount of the second resin may be adjusted to be greater than the supply amount of the first resin, or may be adjusted to be the same as the supply amount of the first resin. Further, when the number of workpieces on which the electronic component is mounted does not reach the specified number, a workpiece on which the electronic component is not mounted (i.e., a dummy workpiece) may be added, and in that case, the second resin is supplied up to the maximum supply amount. In addition, when the supply amount of the first resin varies or is lacking, the shortage or excess may be adjusted by the second resin.

A resin sealing method according to another aspect of the present invention is a compression molding type resin sealing method for sealing an electronic component of a workpiece including a substrate and the electronic component with resin, the resin sealing method including: calculating, for each workpiece, a resin amount of a resin material to be supplied to the workpiece based on a mounting state of the electronic component in the workpiece; supplying the workpiece to a resin sealing mold; supplying a resin material to the resin sealing mold; and sealing the electronic component with resin by compression molding the resin material on the workpiece by the resin sealing mold. The resin material includes a first resin and a second resin, the first resin is a sheet-like resin, the second resin is a granulated resin, a powdered resin, or a liquid resin, and a supply amount of at least the second resin among the first resin and the second resin is determined for each workpiece based on the resin amount of the resin material calculated for each workpiece.

As a result, the amount of resin material may be adjusted according to the mounting state of the workpiece. Thus, a resin sealing method that may supply an appropriate amount of resin to each workpiece while eliminating waste of the resin supplied may be provided.

The embodiment described above is intended to facilitate understanding of the present invention, and is not intended to limit the interpretation of the present invention. Each element included in the embodiment, as well as its arrangement, material, conditions, shape, size, etc., are not limited to those illustrated and may be changed as appropriate. Furthermore, it is possible to replace or combine the configurations shown in the different embodiments partially.

### REFERENCE SIGNS LIST

1 Resin sealing device
10 workpiece supply unit
20, 30 Resin molding unit
21, 31 Resin sealing mold
25, 35 Cavity
27, 37 Film handler
40 Second resin supply unit
44 Resin guard
50 First resin supply unit
60 First loader
61 First loader hand
70 Second loader
71 Second loader hand
80 Resin heater
90 Molded product recovery unit
W workpiece
P Electronic component
B Substrate
R1 First resin
R2 Second resin
F Film

1. A resin sealing device, which is a compression molding type resin sealing device configured to seal an electronic component of a workpiece comprising a substrate and the electronic component with resin, the resin sealing device comprising:
a resin sealing mold, configured to seal the electronic component with resin by compression molding a resin material on the workpiece; and
a resin amount calculation portion, configured to calculate, for each workpiece, a resin amount of the resin material to be supplied to the workpiece based on a mounting state of the electronic component in the workpiece,
wherein the resin material comprises a first resin and a second resin,
the first resin is a sheet-like resin,
the second resin is a granulated resin, a powdered resin, or a liquid resin, and
a supply amount of at least the second resin among the first resin and the second resin is determined for each workpiece based on the resin amount calculated by the resin amount calculation portion.

2. The resin sealing device according to claim 1, wherein the second resin is a resin having identical or different properties as the first resin.

3. The resin sealing device according to claim 1, further comprising:
a first resin supply portion, configured to supply the first resin; and
a second resin supply portion, configured to supply the second resin,
wherein the second resin supply portion is configured to supply the second resin into an opening of a guide portion on the first resin supplied by the first resin supply portion.

4. The resin sealing device according to claim 3, wherein
the resin sealing mold comprises an upper mold and a lower mold, and
the upper mold has a cavity recessed portion opening toward the lower mold.

5. The resin sealing device according to claim 4, further comprising:
a loader hand, configured to transport the resin material to the resin sealing mold,
wherein the second resin has a higher releasability than the first resin, and
the loader hand is configured to provide the first resin and the second resin in the cavity recessed portion with the second resin facing the upper mold.

6. The resin sealing device according to claim 3, wherein
the resin sealing mold comprises an upper mold and a lower mold, and
the lower mold has a cavity recessed portion opening toward the upper mold.

7. The resin sealing device according to claim 6, further comprising:
a loader hand, configured to transport the resin material to the resin sealing mold,
wherein the first resin has a higher releasability than the second resin, and
the loader hand is configured to provide the first resin and the second resin in the cavity recessed portion with the first resin facing the lower mold.

8. The resin sealing device according to claim 1, further comprising:
a first resin supply portion, configured to supply the first resin; and
a second resin supply portion, configured to supply the second resin,
wherein the second resin supply portion is configured to supply the second resin into an opening of a guide portion, and
the first resin supply portion is configured to supply the first resin on the second resin.

9. The resin sealing device according to claim 8, further comprising:
a loader hand, configured to transport the resin material to the resin sealing mold,
wherein the loader hand has a suction pad or an electrostatic chuck.

10. The resin sealing device according to claim 1, further comprising:
a loader hand, configured to transport the resin material to the resin sealing mold,
wherein the loader hand is configured to transport the first resin and the second resin to the resin sealing mold in a state in which the first resin and the second resin are fused together.

11. The resin sealing device according to claim 1, wherein a supply amount of the second resin is determined based on a difference between the resin amount calculated by the resin amount calculation portion and a supply amount of the first resin.

12. The resin sealing device according to claim 1, wherein a supply amount of the second resin is smaller than a supply amount of the first resin.

13. A resin sealing method, which is a compression molding type resin sealing method for sealing an electronic component of a workpiece comprising a substrate and the electronic component with resin, the resin sealing method comprising:
calculating, for each workpiece, a resin amount of a resin material to be supplied to the workpiece based on a mounting state of the electronic component in the workpiece;
supplying the workpiece to a resin sealing mold;
supplying a resin material to the resin sealing mold; and
sealing the electronic component with resin by compression molding the resin material on the workpiece by the resin sealing mold,
wherein the resin material comprises a first resin and a second resin, the first resin is a sheet-like resin, the second resin is a granulated resin, a powdered resin, or a liquid resin, and
a supply amount of at least the second resin among the first resin and the second resin is determined for each workpiece based on the resin amount of the resin material calculated for each workpiece.
